(19) United States
(12) Patent Application Publication
(10) Pub. No.: US 2011/0227650 A1
(43) Pub. Date: Sep. 22, 2011

(54) RECEIVED-LIGHT AMPLIFYING CIRCUIT AND OPTICAL DISC APPARATUS

(75) Inventors: Shinichi MIYAMOTO, Kyoto (JP); Hideo FUKUDA, Kyoto (JP)

(73) Assignee: PANASONIC CORPORATION, Osaka (JP)

(21) Appl. No.: 13/150,588

(22) Filed: Jun. 1, 2011

Related U.S. Application Data
(63) Continuation of application No. PCT/JP2009/006604, filed on Dec. 3, 2009.

(30) Foreign Application Priority Data
Dec. 3, 2008 (JP) 2008-309170

(51) Int. Cl. H03F 3/45

(52) U.S. Cl. 330/254

(57) ABSTRACT

A received-light amplifying circuit includes: an amplifier AMP1 converting a current signal provided from a light-receiving element into a voltage signal; differential voltage amplifying circuits AMP2 and AMP3 each of which has a non-inverting input terminal connected to the AMP1; an output connected commonly to the AMP2 and the AMP3; feedback resistors R2 and R4 connected between the output and one of inverting inputs of the AMP2 and the AMP3 respectively; gain resistors R1 and R3 connected between a reference voltage and the one of inverting inputs respectively; a switch SW1 connected, between the output and the reference voltage, in series to the R1 and the R2; and a switch SW2 connected, between the output terminal and the reference voltage, in series to the R3 and the R4, the SW1 and the SW2 controlling a connection between the output terminal and the reference voltage in response to a signal SW.

### CROSS REFERENCE TO RELATED APPLICATION

This is a continuation application of PCT application No. PCT/JP2009/006604 filed on Dec. 3, 2009, designating the United States of America.

### BACKGROUND OF THE INVENTION

(1) Field of the Invention

The present invention relates to semiconductor devices including light-receiving elements and, in particular, to a received-light amplifying circuit including a gain-switching circuit employing a switching device.

(2) Description of the Related Art

In response to the increase in disc revolution speed during the reading of data, as well as the writing of data into various types of optical discs in optical disc apparatuses represented by Blu-ray (BD) disc apparatuses and Digital Versatile Disc-Recordable (DVD-R) drive apparatuses and, in recent years there has been a demand for received-light amplifiers that can precisely amplify both of high frequency signals during data reading and pulse signals during data writing. Such received-light amplifiers work by the switching between the frequency bands and the output voltages in accordance with the input signal.

FIG. 1 is a circuit diagram exemplifying how a received-light amplifying circuit disclosed in Patent Reference 1 (Japanese Unexamined Patent Application Publication No. 2004-288243) is used. The received-light amplifying circuit in FIG. 1 includes the following: a light-receiving element PD1; amplifiers AMP1, AMP2, and AMP3 which operationally amplify the current provided from the PD1; a conversion resistor Rg_A which converts a current provided from the PD1 into a voltage; feedback resistors R2 and R4, and gain resistors R1 and R3 which determine gains of the AMP2 and the AMP3; and an output terminal. The received-light amplifying circuit receives a reference voltage Vref which determines a reference of an output voltage. In Patent Reference 1, each of the outputs from the AMP2 and the AMP3 connects to a different terminal. However, the outputs from the AMP2 and the AMP3 in FIG. 1 are assumed to be connected to the same output terminal, which exhibits a clear comparison between the present invention and Patent Reference 1.

The inverting input terminal of the AMP1 connects to the cathode of the light-receiving element PD1. The anode of the light-receiving element PD1 is grounded. The non-inverting input terminal of the AMP1 connects to the reference voltage Vref via an impedance matching resistor Rref_A. A current-voltage conversion resistor Rg_A is connected between the inverting input terminal and the output terminal of the AMP1.

The output of the AMP1 connects to the non-inverting input terminals of the AMP2 and the AMP3. The feedback resistor R2 is connected between the output terminal and the inverting input terminal of the AMP2. The feedback resistor R4 is connected between the output terminal and the inverting input terminal of the AMP3. The gain resistor R1 is connected between the inverting input terminal of the AMP2 and the reference voltage Vref. The gain resistor R3 is connected between the inverting input terminal of the AMP3 and the reference voltage Vref.

The gains of the AMP2 and AMP3 are respectively determined by (R1+R2)/R1 and (R3+R4)/R3. The reflectance of the optical disc differs in writing and in reading a signal to and from the disc, for example. Thus switching between the AMP2 and the AMP3, each having a different gain, makes possible providing an output voltage having the optimum amplitude in each case.

Despite the difference of optical disc standards and the difference between reading and writing, the above conventional technique can obtain a constant output voltage with the selective use of the amplifiers each having the optimum gain according to an intensity of the light which is reflected from the disc and enters into a light-receiving device. Hence the conventional technique can handle different optical discs in standard, and in reading and writing.

The circuit in FIG. 1, however, supplies a current evaluated with the following expression when the light-receiving element PD1 receives light and the output terminal delivers the output voltage Vo:

(Vo−Vref)/((R1+R2)//(R3+R4)) (Expression 1)

where // represents a parallel sum of the resistors
Such a current is provided from the output terminals of the AMP2 and the AMP3 to Vref, and the voltage drop developed by a parasitic impedance Z of a supply line for Vref inevitably enters the non-inverting input terminal of the AMP1. This causes problems such as poor high-frequency characteristics and oscillations.

Here the parasitic impedance Z is developed by a resistance and an inductance of an aluminum line found in an integrated circuit or in a line printed on a substrate on which an integrated circuit is mounted. Ideally, the parasitic impedance Z should be reduced to zero; however, the lines prevent the parasitic impedance Z from being eliminated. In addition, greater resistances at the resistors R1, R2, R3, and R4 result in poorer frequency characteristics due to the filter effect caused by the resistances and the parasitic capacitances of the resistors. Hence the resistances cannot be increased more than are necessary.

In order to handle various kinds of media, such as a BD, a DVD-R, a DVD-Random Access Memory (RAM), a DVD-Rewritable (RW), and a Compact Disc (CD), a wider variety of choices in gain are required for each medium. An approach to meet this requirement would be to install more amplifiers having different feedback resistances and gain resistances. This solution, however, causes a decrease in the sum of parallel resistances; namely, the denominator of Expression 1, and increases the current provided to Vref. The result is a relatively growing effect of the parasitic impedance Z found in the supply line of the Vref.

The conventional received-light amplifying circuit dedicated to the CD and the DVD has a limited number of choices in required gain, and has relatively low frequencies of signals to be processed. Thus the parasitic impedance Z does not significantly affect the conventional received-light amplifying circuit, and is not a problem thereto. However, for a received-light amplifying circuit which processes high-frequency signals for a BD, the effect of a parasitic inductance which causes the parasitic impedance Z grows in proportion to the frequency of a signal to be processed. Hence the effect of the parasitic impedance Z, due to the decrease in the sum of the parallel resistances, becomes too large to ignore.

To decrease the parasitic impedance Z found in the supply line of Vref, the following measures are effective; installing a thicker supply line for Vref, and closing the distance between the received-light amplifying circuit and a bypass capacitor (not shown) connecting to the power terminal of the received-light amplifying circuit. Unfortunately, such measures fail to provide a realistic solution to the problem. This is because the layout of the devices is restricted since an optical pickup device goes thinner as lately typified by an optical disk drive for a laptop computer. Consequently, the market requires lines having a narrower width.

The present invention is conceived in view of the above problem and has an object to provide received-light amplifying circuits including a gain-switching circuit and, in particular, a received-light amplifying circuit which handles various kinds of media and shows excellent high-frequency characteristics.

### SUMMARY OF THE INVENTION

In order to achieve the above object, a received-light amplifying circuit according to an implementation of the present invention includes: a current-voltage conversion circuit which converts a current signal provided from a light-receiving element into a voltage signal; differential voltage amplifying circuits each of which has a non-inverting input terminal connected to an output terminal of the current-voltage conversion circuit; an output terminal which has a common connection to output terminals of the differential voltage amplifying circuits; feedback resistors each of which is connected between the output terminal and an inverting input terminal of a corresponding one of the differential voltage amplifying circuits; gain resistors each of which is connected between the inverting input terminal of the corresponding one of the voltage amplifying circuits and a reference voltage; and one or more control units each of which is (i) provided with the corresponding one of the differential voltage amplifying circuits, (ii) connected, between the output terminal and the reference voltage, in series to a corresponding one of the feedback resistors and to a corresponding one of the gain resistors, and (iii) controls a connection between the output terminal and the reference voltage in response to a signal from an outside.

Each of the control unit may be a switch connected between the gain resistor and the reference voltage. In response to the signal from outside, any one of the differential voltage amplifying circuits is selectively activated, and any one of the switches for disabled one of the differential voltage amplifying circuits turns off.

According to the structure, the control unit breaks the return path of a disabled voltage amplifying circuit in order to reduce the current running from the output terminal to the supply source of the reference voltage. Accordingly, the reduction of the current decreases the voltage drop developed according to the impedance of the supply line of the reference voltage.

Since the voltage drop causes feedback to the current-voltage conversion circuit in the form of an undesired signal component, the received-light amplifying circuit will have poor high high-frequency characteristics. Thus the reduction in the voltage drop is beneficial to a decrease in deterioration of the high-frequency characteristics.

The above structure may be applied to a received-light amplifying circuit having many voltage amplifying circuits each having a different gain. In such a case, the received-light amplifying circuit is particularly successful to stop the currents running from return paths of many disabled voltage amplifying circuits to the reference supply. Thus the structure is significantly effective in decreasing the deterioration of the high-frequency characteristics of the received-light amplifying circuit.

As described above, the received-light amplifying circuit of the present invention successfully achieves excellent high-frequency characteristics which are required for flawless processing of signals provided from a BD, as well as signals from conventional media including a DVD-R, a DVD-RAM, a DVD-RW, and a CD.

### FURTHER INFORMATION ABOUT TECHNICAL BACKGROUND TO THIS APPLICATION

The disclosure of Japanese Patent Application No. 2008-309170 filed on Dec. 3, 2008, including specification, drawings and claims is incorporated herein by reference in its entirety.

The disclosure of PCT application No. PCT/JP2009/006604 filed on Dec. 3, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a circuit diagram exemplifying how a conventional received-light amplifying circuit is used;

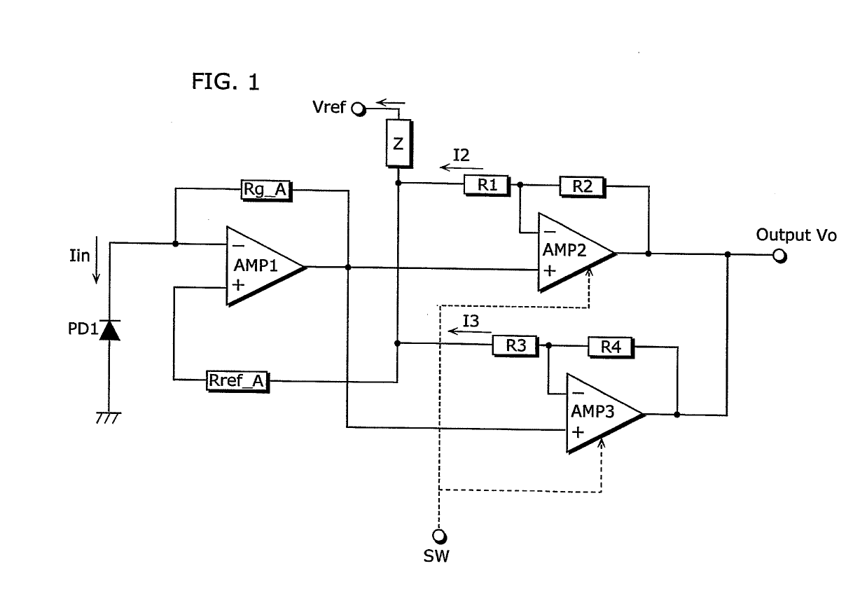

FIG. 2 is a circuit diagram exemplifying a received-light amplifying circuit according to Embodiment 1;

FIG. 3 shows how a voltage drop occurs in a supply line for Vref;

FIG. 4 is a circuit diagram exemplifying a modification of the received-light amplifying circuit according to Embodiment 1;

FIG. 5 is a circuit diagram exemplifying a modification of the received-light amplifying circuit according to Embodiment 1;

FIG. 6 is a circuit diagram exemplifying a modification of the received-light amplifying circuit according to Embodiment 1;

FIG. 7 exemplifies temperature characteristics of an offset voltage;

FIG. 8 is a circuit diagram exemplifying a buffer circuit according to the modifications in Embodiment 1;

FIG. 9 is a circuit diagram exemplifying a received-light amplifying circuit according to Embodiment 2;

FIG. 10 is a circuit diagram showing a comparison example of a voltage amplifying circuit;

FIG. 11 is a circuit diagram exemplifying a modification of the received-light amplifying circuit according to Embodiment 2;

FIG. 12 is a circuit diagram showing a comparison example of a voltage amplifying circuit;

FIG. 13 shows open-loop gains of the received-light amplifying circuits according to the modification in Embodiment 2;

FIG. 14 is a circuit diagram exemplifying a modification of the received-light amplifying circuit according to Embodiment 2;

FIG. 15 shows output voltage characteristics of the received-light amplifying circuit according to the modification in Embodiment 2;

FIG. 16 is a circuit diagram exemplifying a received-light amplifying circuit according to Embodiment 3; and

FIG. 17 exemplifies an optical disc apparatus using the received-light amplifying circuit in the present invention.

### DESCRIPTION OF THE PREFERRED EMBODIMENTS

### Embodiment 1

Described hereinafter is a received-light amplifying circuit according to Embodiment 1 of the present invention with reference to the drawings.

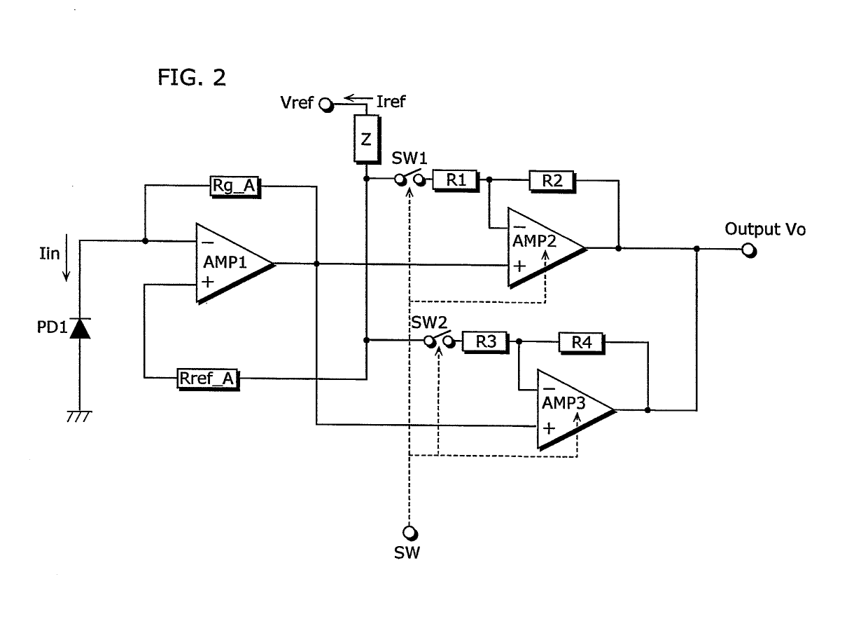

FIG. 2 exemplifies the received-light amplifying circuit according to Embodiment 1 of the present invention. As FIG. 2 shows, the inverting input terminal of an amplifier AMP1 is connected to the cathode of a light-receiving element PD1. Here the amplifier AMP1 works as a current-voltage conversion circuit. The anode of the PD1 is connected to the ground potential. In addition, a current-voltage conversion resistor Rg_A is connected between the inverting input terminal and the output terminal of the AMP1. An impedance matching resistor Rref_A is connected between the non-inverting input terminal of the AMP1 and a reference voltage Vref. The output of the AMP1 is connected to each of non-inverting input terminals of amplifiers AMP2 and AMP3. Here, the AMP2 and AMP3 work as non-inverting voltage amplifying circuits.

A feedback resistor R2 is connected between the inverting input terminal and the output terminal of the AMP2. A gain resistor R1 and an SW1 are connected with each other in series between the inverting input terminal of the AMP2 and the reference voltage Vref. Similarly, a feedback resistor R4 is connected between the inverting input terminal and the output terminal of the AMP3. A gain resistor R3 and an SW2 are connected with each other in series between the inverting input terminal of the AMP3 and the reference voltage Vref. As described above, the gains of the AMP2 and AMP3 are respectively determined by (R1+R2)/R1 and (R3+R4)/R3. A different gain is set for each of the AMP2 and the AMP3.

The AMP2 and the AMP3 are controlled by an SW signal so that one of the AMP2 and the AMP3 whichever can have the set gain is activated, and the other is disabled. The SW1 and the SW2 are operated by the SW signal so that either the SW1 or the SW2 turns off when one of the AMP2 and the AMP3, respectively connected to the SW1 and the SW2, is disabled. In general, the SW signal is a control signal supplied from the outside.

Described next is an operation of the received-light amplifying circuit according to Embodiment 1. When an optical disc having a relatively high reflectance is reproduced, a large amount of the reflected light enters into a PD1. Hence one of the AMP2 and the AMP3 whichever has a lower gain is selectively activated. Hereinafter assumed is the case where the gain of the AMP2 is set lower than that of the AMP3.

A photocurrent Iin generated by the PD1 enters into the AMP1, and is converted into a voltage. The output voltage of the AMP1, which is referred to as Iin×Rg_A, is delivered with reference to the reference voltage Vref. The signal Iin×Rg_A enters into the AMP2, and is multiplied by (R1+R2)/R1. Consequently, the output voltage of Vo=Iin×Rg_A×(R1+R2)/R1 is obtained on the output terminal.

Here the conventional technique develops the following: The current Iref=(Vo−Vref)/((R1+R2)//(R3+R4)) is provided to the supply source of Vref, and the voltage drop of Z×(Vo−Vref)/((R1+R2)//(R3+R4)) is developed by the parasitic impedance Z of a supply line for Vref. In the present invention, turning the SW1 on and the SW2 off can reduce the current to as little as Iref=(Vo−Vref)/(R1+R2). Hence the voltage drop by Z can be reduced to Z×(Vo−Vref)/(R1+R2).

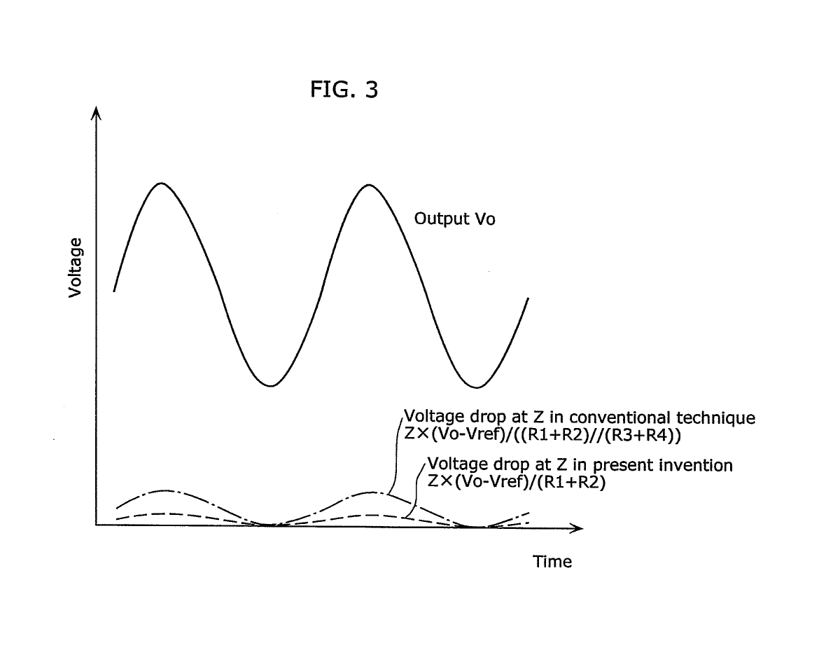

FIG. 3 schematically illustrates the comparison between the voltage drops developed at Z and observed in the conventional technique and the present invention. When a light signal having a sine wave is emitted to the light-receiving element, an output voltage having the sine wave can be obtained from the output Vo. Here the voltage drop observed at Z shows the sine wave. Iref in the present invention is smaller than that in the conventional technique. Since the amplitude of the sine wave in the voltage drop is smaller, the voltage drop observed at Z in the present invention is small as well.

The voltage fluctuation in response to the voltage drop at Z enters into the non-inverting input terminal of the AMP1 as a positive feedback to the AMP1 and the AMP2, which causes the oscillation and deterioration in high-frequency characteristics. The voltage drop at Z in the present invention is smaller than that in the conventional technique. Thus the present invention successfully reduces the oscillation and the deterioration in high-frequency characteristics.

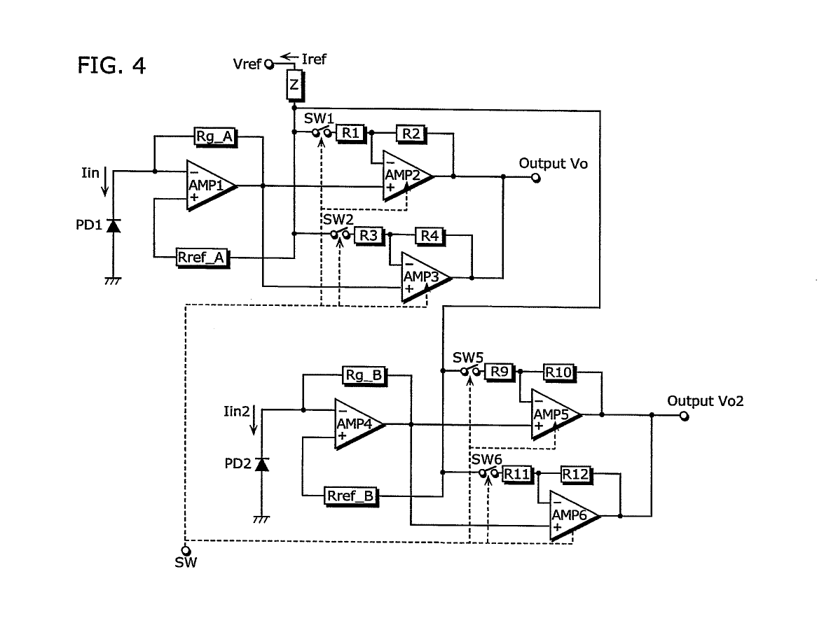

FIG. 4 is a circuit diagram exemplifying an application modification of the received-light amplifying circuit shown in FIG. 2 for use in optical pickup. As shown in FIG. 4, a typical received-light amplifying circuit for the optical pick up employs either the sum of or the difference between amounts of the received light to operate the servomechanism or to the tracking mechanism for the optical pick up. Hence the received-light amplifying circuit includes multiple light-receiving elements. FIG. 4 exemplifies a case where the received-light amplifying circuit includes two light-receiving elements; namely the PD1 and a PD2. The current signal obtained from each of the light-receiving elements PD1 and PD2 is provided with the same current-voltage conversion efficiency. In order to match the current-voltage conversion efficiencies, all the resistors are typically designed to have the following resistances; Rg_A=Rg_B, Rref_A=Rref_B, R1=R9, R2=R10, R3=R11, and R4=R12.

For example, the photocurrent Iin generated by the PD1 enters into the AMP1, and is converted into a voltage with use of the gain of the Rg_A. The output voltage of the AMP1 is delivered to the AMP2 and to the AMP3. One of the AMP2 and the AMP3, which is selected by the SW signal, amplifies the output voltage to generate the output voltage Vo, using either (i) the gain determined by the R1 and the R2 or (ii) the gain determined by the R3 and the R4. The SW1 turns on when the AMP2 is selected. The SW2 turns on when the AMP3 is selected.

Similarly, the photocurrent Iin2 generated by the PD2 enters into the AMP4, and is converted into a voltage with the use of the gain of the Rg_B. The output voltage of the AMP4 is delivered to the AMP5 and to the AMP6. One of the AMP5 and the AMP6, which is selected by the SW signal, amplifies the output voltage to generate the output voltage Vo2, using either (i) the gain determined by the R9 and the R10 or (ii) the gain determined by the R11 and the R12. The SW5 turns on when the AMP5 is selected. The SW6 turns on when the AMP6 is selected.

It is noted that the resistances of the Rref_A and the Rref_B are set in order to match the impedances observed with respect to the inverting input terminal and non-inverting input terminal of each of the AMP1 and the AMP4. This reduces the development of an offset voltage.

A calculation is executed, using a sum signal and a differential signal of Vo and Vo2. This allows the servo mechanism and the tracking mechanism to carry out the optical pick-up. Consider the photocurrent Iin generated by the PD1. In response to Iin, Iref develops the voltage drop at Z. The voltage drop inevitably enters into the non-inverting input terminal of each of the AMP1 and the AMP4. Hence Vo2 receives the voltage fluctuation caused in response to Iin, which leads to crosstalk. Greater crosstalk prevents Vo2 from accurately showing the amount of received light from the PD2, and this causes malfunctions of the servomechanism or the tracking mechanism for the optical pick up. The present invention can also reduce such malfunctions.

It is noted that FIG. 4 shows a structure with two light-receiving elements; namely, the PD1 and the PD2. In the case where more than two light-receiving elements are provided, the conventional technique would suffer from greater Iref. Hence the present invention will be effective as more light-receiving elements are provided.

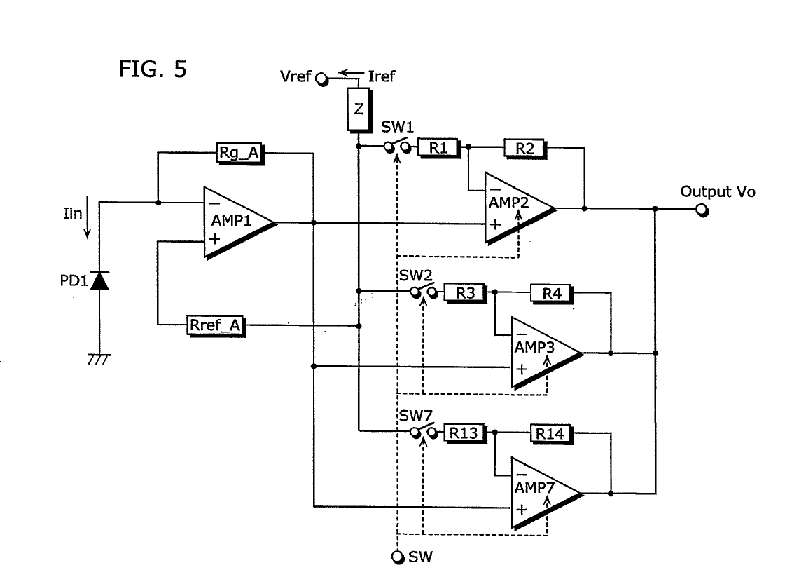

FIG. 2 shows the case where two kinds of gains are employed; concurrently, FIG. 5 exemplifies the case where three kinds of gains are employed. An R13, an R14, and an AMP7 are added to the received-light amplifying circuit in FIG. 2. This structure allows the received-light amplifying circuit in FIG. 5 to have the third kind of gain. The AMP2, the AMP3, and the AMP7 may be designed to be activated by the SW signal, so that (i) the AMP2, the AMP3, and the AMP7 independently work or (ii) two or more of the amplifiers simultaneously work. This structure makes possible having a wider variety of choices in gain, which contributes to employing many kinds of gains within a circuit having a limited size.

Similar to the case of FIG. 2, the SW1, the SW2, and an SW7 turn on when the AMP2, the AMP3, and the AMP7 are respectively selected. Accordingly, the increase in Iref is curbed. This structure allows the received-light amplifying circuit in FIG. 5 to achieve the effects of the present invention.

In particular, the recent growth in the variety of optical discs increases the kinds of gains which received-light amplifying circuits have to handle. Without the present invention, the denominator of Expression 1 is smaller as the variety of choices in gain increases. This results in a greater voltage drop caused by Z as described above, leading to greater oscillation and deterioration in high-frequency characteristics. The use of the present invention causes the voltage drop by Z to depend only on the resistors which determine the gains required accordingly, instead of depending on the number of the kinds of the gains. In the case where the AMP2 independently is activated, for example, the voltage drop by Z can be reduced to Z×(Vo−Vref)/(R1+R2).

It is noted that the received-light amplifying circuit in FIG. 5 may also have an extra amplifier, so that the circuit can employ a greater variety of choices in gain.

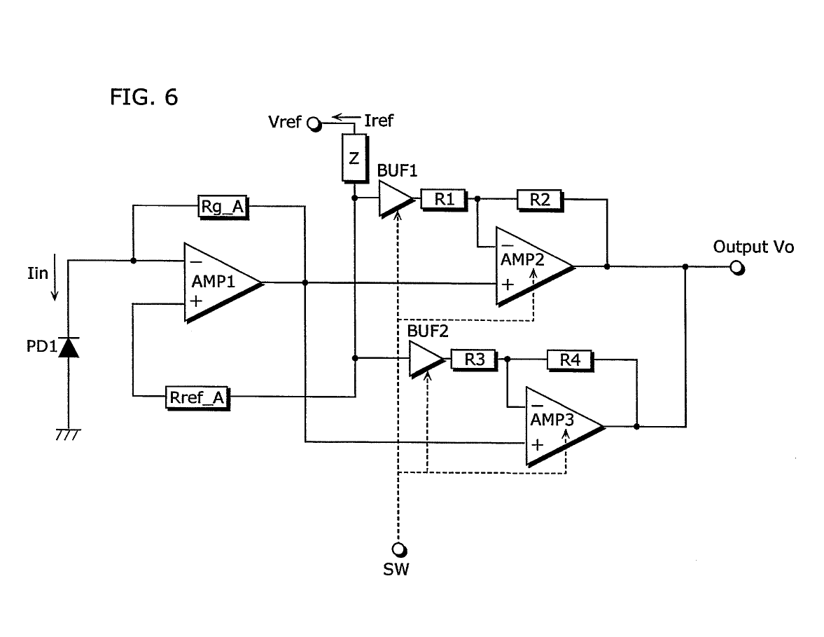

FIG. 6 is a circuit diagram exemplifying an application modification of the received-light amplifying circuit shown in FIG. 2. The SW1 and the SW2 in FIG. 2 are respectively replaced with buffer circuits BUF1 and BUF2. Each of the BUF1 and the BUF2 is turned on and off by the SW signal.

For example, when (i) the buffer circuit BUF1 and the AMP2 are disabled, and (ii) the BUF2 and the AMP3 are activated, the impedance of the connection between the R1 and the BUF 1 goes high, so that a current is not supplied to R1, and the gain is determined to be (R3+R4)/R3.

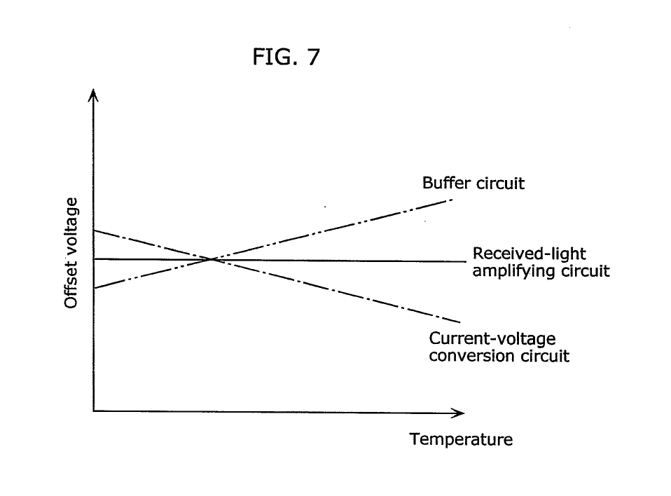

The amplifier AMP1, which works as a current-voltage conversion circuit, develops an offset voltage due to manufacturing variations of transistors and resistors. FIG. 7 exemplifies temperature characteristics of the offset voltage. The greater temperature dependency the offset voltage has, the larger deviation the offset has when the temperature changes in optical pick up. As a result, the servo mechanism fails to track correctly. In an example of FIG. 7, the offset voltage of the AMP1 decreases as the temperature rises. Here the temperature characteristics of the output from the buffer circuit may be set to have the curve opposite the temperature characteristics of the offset voltage, so that the temperature dependency of the offset voltage is canceled when the received-light amplifying circuit has the output voltage Vo.

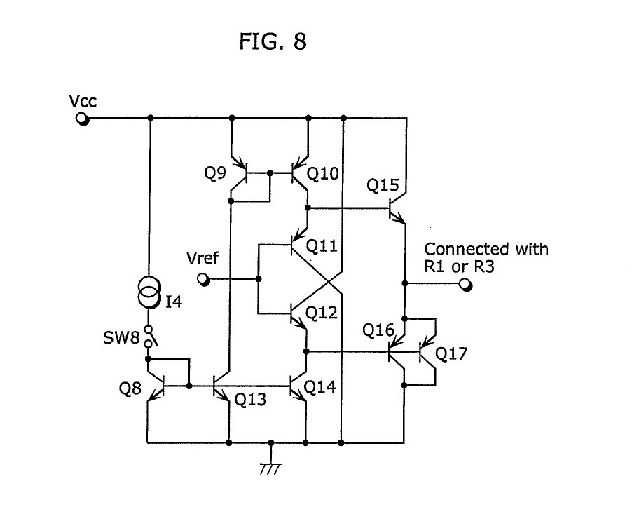

FIG. 8 exemplifies one of the buffer circuits. A Q11, a Q12, a Q15, a Q16, and a Q17 form a complementary symmetry emitter follower. A Q8, a Q9, a Q10, a Q13, and a Q14 form a current miller for supplying an output current of a constant current source 14 as a drive current. A SW8 turns on and off the current conducted into the buffer circuit, and causes the buffer circuit to activate and disable.

The Q16 and the Q17 are connected with each other in parallel, so that the voltage between the base and the emitter of the Q15 changes. The difference in temperature characteristic of the base-emitter voltage controls the temperature characteristics of the output voltage provided from the buffer circuit. When the buffer circuit in FIG. 8 is used as the received-light amplifying circuit, Iref includes nothing but the input current from the buffer circuit. This contributes to curbing a further voltage drop by Z.

### Embodiment 2

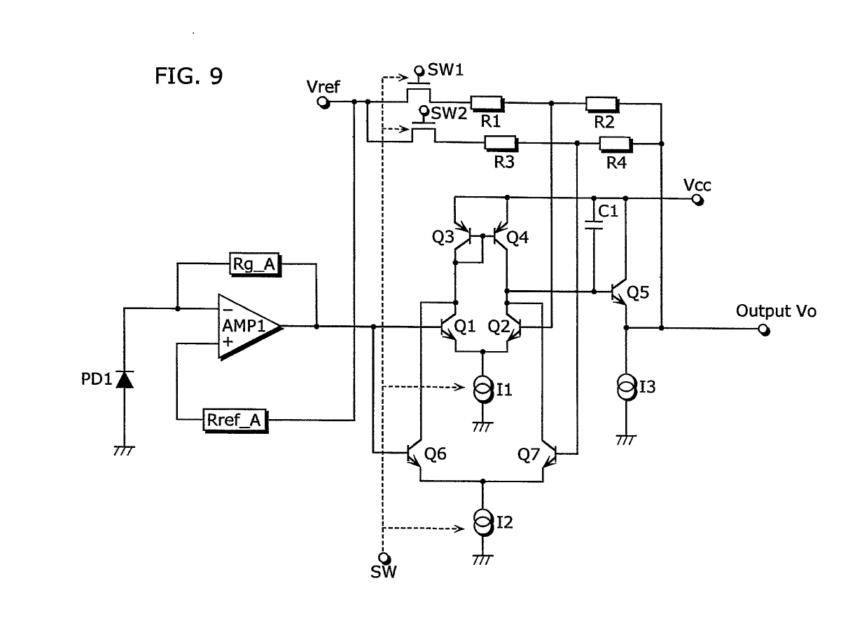

FIG. 9 is a circuit diagram exemplifying a received-light amplifying circuit according to Embodiment 2.

The following corresponds to the AMP2 shown in FIG. 2: a pair of transistors Q1 and Q2, current millers Q3 and Q4 which work as loads of the pair of the transistors Q1 and Q2, an emitter follower Q5, a phase compensation capacitor C1, and constant current sources I1 and I3.

The following corresponds to the AMP3 shown in FIG. 2: a pair of transistors Q6 and Q7, the current millers Q3 and Q4 which work as loads of the pair of the transistors Q6 and Q7, the emitter follower Q5, the phase compensation capacitor C1, and constant current sources 12 and I3.

The constant current source I1 drives the Q1 and the Q2, and the constant current source I2 drives the Q6 and the Q7. The constant current source I3 drives the Q5.

Here the pairs of the transistors Q1 and Q2 and the Q6 and Q7 are an example of differential amplifying units, and correspond to the AMP1 and the AMP2. The emitter follower Q5 is an example of a buffer unit for both of the AMP1 and the AMP2.

The SW1 and the SW2 are MOS transistors, for example. The base of the Q2 is connected to the feedback resistor R2, and to the gain resistor R1. The base of the Q7 is connected to the feedback resistor R4, and to the gain resistor R3. In order to reduce the current Iref flowing into Vref, the SW1 and the SW2 are respectively provided between the R1 and Vref, and between the R3 and Vref.

The SW signal selectively activates the I1, the I2, the SW1, and the SW2. When the I1 and the SW1 are activated, the gain (R1+R2)/R1 is obtained. When the I2 and the SW2 are activated, the gain (R3+R4)/R3 is obtained.

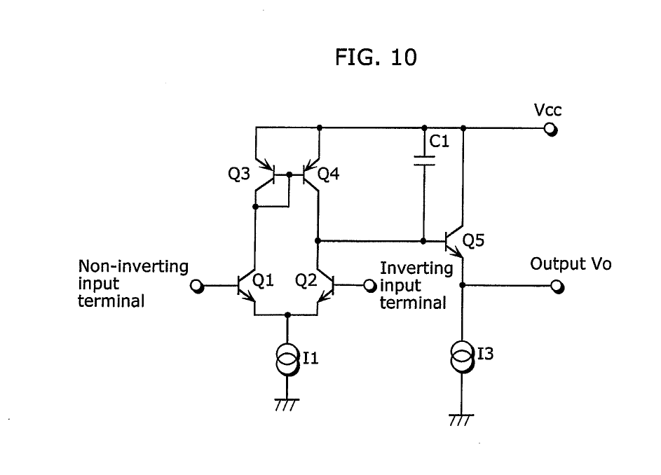

As a comparison example, FIG. 10 exemplifies a circuit diagram of the AMP2 or the AMP3 when each of the AMP2 and the AMP3 is independently configured. Each of the AMP2 and the AMP3 includes the Q1 to the Q5, the I1, the I3, and the C1. Compared with the circuit shown in FIG. 10, the circuit shown in FIG. 9 has the Q3 to the Q5, the C1 and the I3 shared between the AMP2 and the AMP3. Thus the circuit in FIG. 9 uses fewer devices, and contributes to reducing the cost of the received-light amplifying circuit.

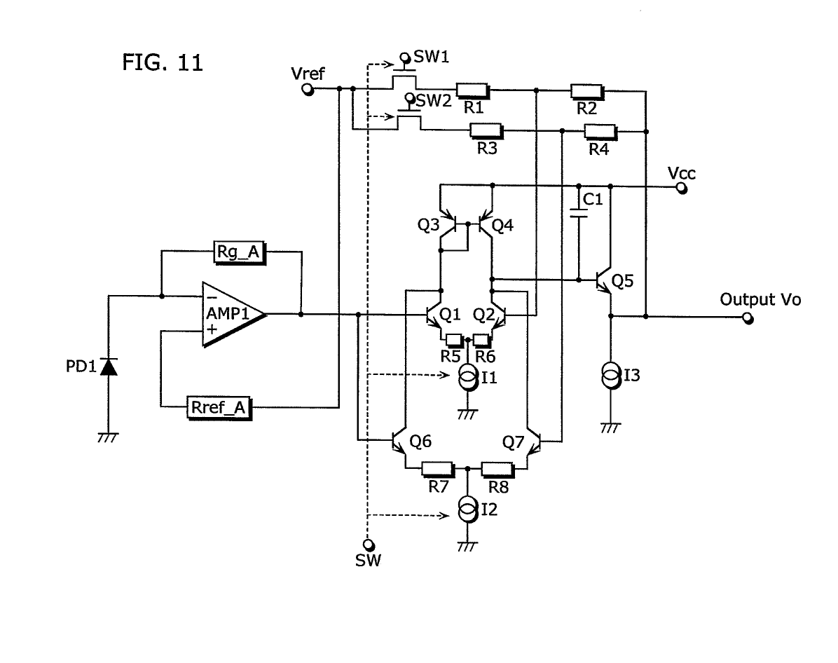

FIG. 11 is a circuit diagram showing an application modification of the received-light amplifying circuit in FIG. 9. Compared with the received-light amplifying circuit in FIG. 9, the received-light amplifying circuit in FIG. 11 is configured as follows: A pair of differential transistors; namely emitters Q1 and Q2, are respectively connected to an R5 and an R6, and a pair of differential transistors; namely emitters Q6 and Q7, are respectively connected to an R7 and an R8.

When RSW is the on-resistance (the on-resistance of the MOS transistors when the MOS transistors are used as switches) of the SW1 and the SW2 in the received-light amplifying circuit of FIG. 9, either gain (R1+R2+RSW)/(R1+RSW) or (R3+R4+RSW)/(R3+RSW) can be selected by the SW signal.

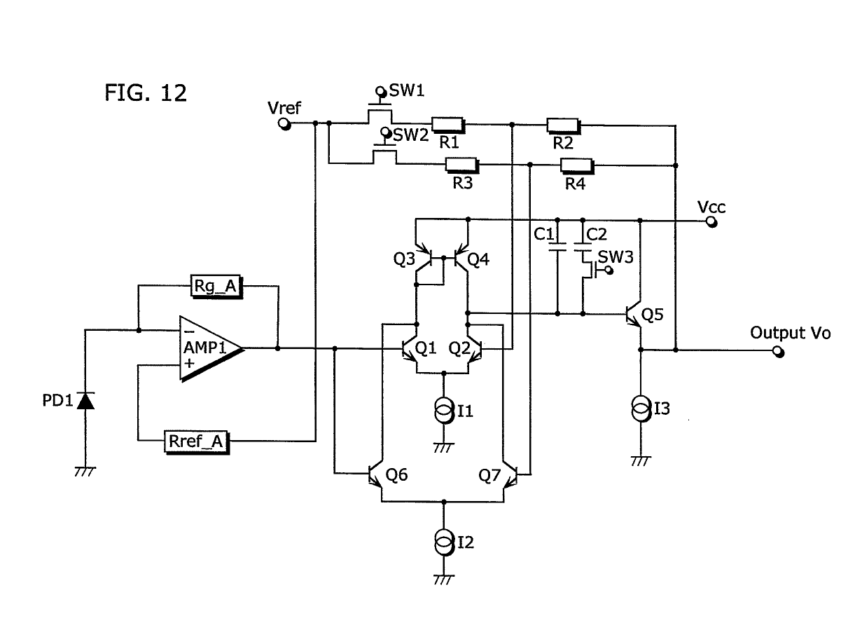

Here suppose the case where the difference between the two gains is great. Selecting a lower gain could cause oscillation and peaking in a high-frequency range since an open loop gain of the pair of differential transistors is excessively high. As a comparison example, FIG. 12 shows a typical circuit used as a counter measure of the above problem.

In addition to the circuit in FIG. 9, the circuit in FIG. 12 further includes a phase compensation capacitor C2, and an SW3 which controls the connection of the C2. The SW3 turns on and off in conjunction with the operations of the SW1 and the SW2, and switches between the phase compensation capacitors C1 and C2 to select the appropriate phase compensation capacitor for the selected gain.

The circuit in FIG. 12, however, requires extra devices to be used as the SW3 and the C2. Such an increase in the number of devices would lead to an increase in the cost and an amount of the capacitance. This develops a new problem such that a slew rate, which is determined by (i) a differential current from either the constant current source I1 or I2, and (ii) the phase compensation capacitors, becomes lower. Thus, this circuit is short of obtaining high-frequency characteristics which are sufficient enough for generating high-frequency signals.

When the gain (R3+R4)/R3 is lower than the gain (R1+R2)/R1, the circuit in FIG. 11 has the resistances of the R7 and the R8 set greater than those of the R5 and the R6. Hence the open loop gains of the pair of the differential transistors Q6 and Q7 can be reduced, using the resistors alone with no extra phase compensation capacitors and the switches controlling the phase compensation capacitors. This structure allows contributes to curbing a rising cost due to extra devices and to reducing the oscillation and the peaking in a high-frequency range in this mode, and makes the circuit in FIG. 11 suitable for generating higher-frequency signals to be used for, for example, the BD. These features make the circuit in FIG. 11 advantageous over the circuit in FIG. 12 with no such features.

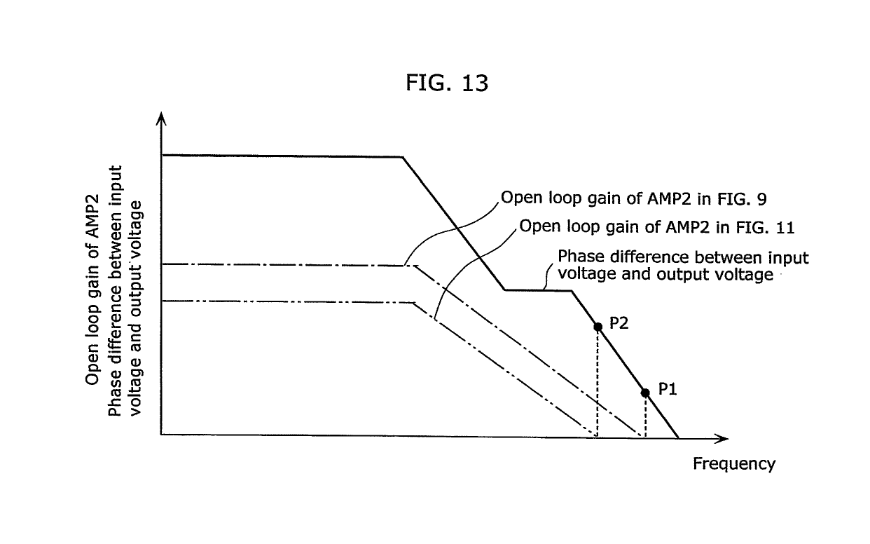

FIG. 13 shows open-loop gains of the circuits in FIGS. 9 and 11. The one-dot dashed line represents the open loop gain of the frequency of the AMP2 in FIG. 9. The two-dot dashed line represents the open loop gain of the frequency of the AMP2 in FIG. 11. The solid line represents the phase difference between the input voltage and the output voltage.

In FIG. 13, P1 and P2 respectively show the phase margins of the AMP2 in FIG. 9 and the AMP2 in FIG. 11. The circuit in FIG. 11 uses the R7 and the R8 to reduce the open loop gain of the AMP2, and makes the P2 greater than the P1. Hence the circuit successfully reduces the oscillation and the peaking in a high-frequency range.

In particular, when the peaking occurs in a high-frequency range, the frequency increases Iref. Such an increase causes Z to develop feedback, and affects the frequency characteristics of the AMP1. The circuits in FIGS. 9 and 11 can reduce the feedback by the SW1 and the SW2, which shows a great improvement in the frequency characteristics.

Furthermore, a greater capacitance of the phase compensation capacitor causes a further decrease in the slew rate indicating the response speeds of the AMP2 and the AMP3. The circuit in FIG. 11, however, shows no increase in the phase compensation capacitor, nor shows the decrease in the slew rate.

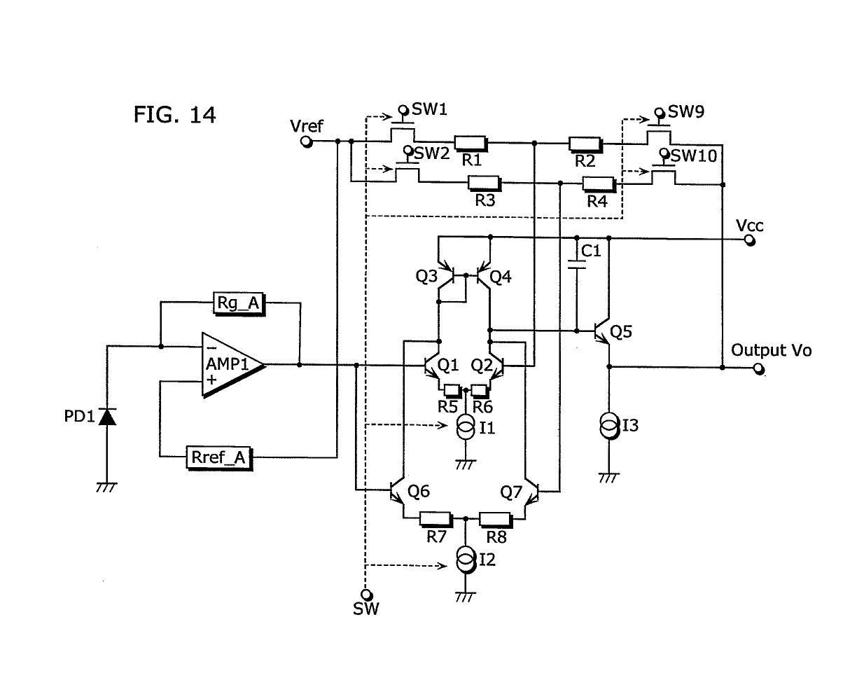

FIG. 14 is a circuit diagram showing an application modification of the received-light amplifying circuit in FIG. 11. An SW9 is connected between the feedback resistor R2 and the output Vo. An SW10 is connected between the feedback resistor R24 and the output Vo. The received-light amplifying circuit operates as follows: When the SW signal is inputted and the high voltage is selected, for example, (i) the I1, the SW1, and the SW9 turn on and the I2, (ii) the SW2, and the SW10 turn off, and (iii) the gain goes (R1+R2+2×RSW)/(R1+RSW). RSW varies according to a running current. Thus when the on-resistance cannot be ignored with respect to the resistance of the R1 or the R3, the gain shows unignorablly poor linearity. In other words, the variation in the output voltage causes a variation in a current running in RSW. This results in a deterioration of the gain in linearity.

For example, consider the case where the SW9 and the SW10 respectively have the same structures as the SW1 and the SW2 have, and R1=5Ω, R2=10 kΩ, and RSW=500Ω. When RSW changes to 250Ω, the distortion figure of the gain is approximately 3.1%. In FIG. 14, the distortion figure can be reduced to 1.5%.

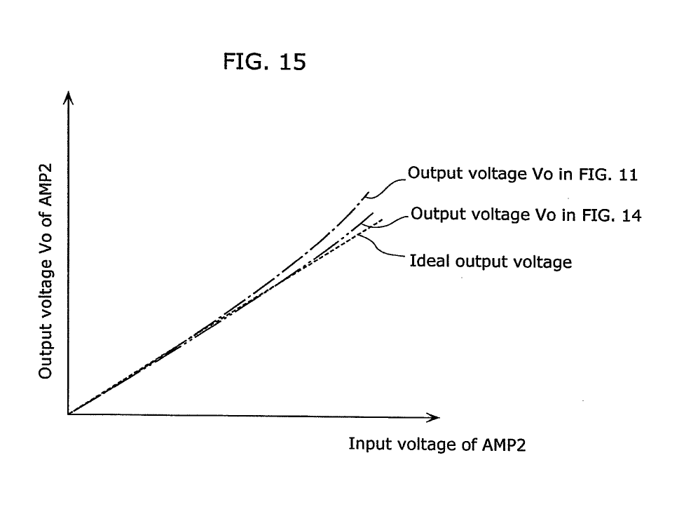

FIG. 15 shows the relationships between the input voltage and the output voltage in FIG. 11 and the input voltage and the output voltage in FIG. 14. Thanks to the SW9 and the SW10 provided with the received-light amplifying circuit in FIG. 14, the distortion of input-output characteristics (the distortion in gain) in FIG. 11 is eased as shown in the output voltage of FIG. 14. Hence the output voltage characteristics are closer to ideal ones.

Hence, by additionally including the SW9 and the SW10 having the same structure as the SW1 and the SW2 have, the received-light amplifying circuit in FIG. 14 successfully reduces the distortion figure of the gain. This structure improves the linearity of the output voltage with respect to the incoming light power to the received-light amplifying circuit, and makes the amplifying circuit suitable to optical power monitors.

### Embodiment 3

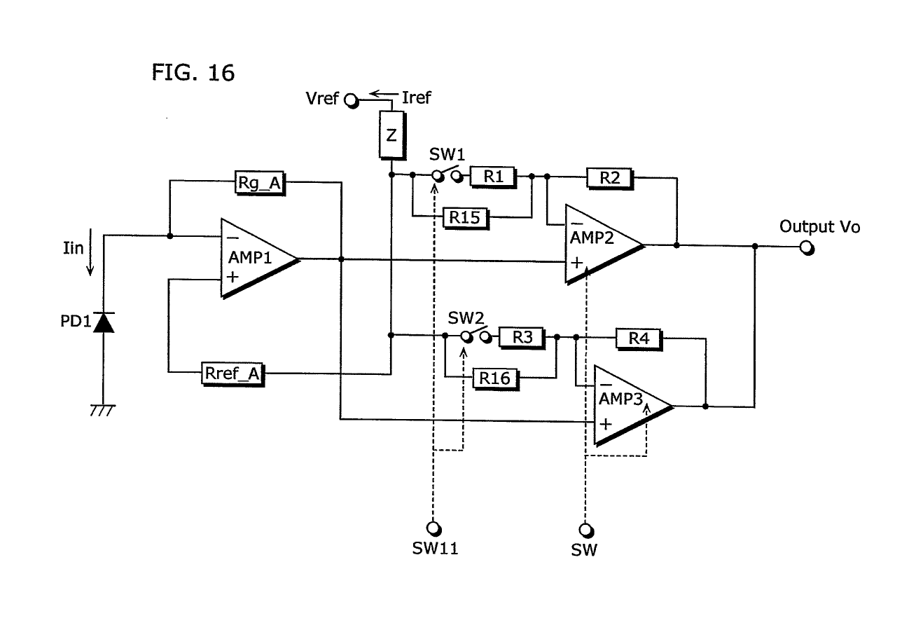

FIG. 16 exemplifies a received-light amplifying circuit according to Embodiment 3. As FIG. 16 shows, the inverting input terminal of the amplifier AMP1 is connected to the cathode of the light-receiving element PD1. Here the amplifier AMP1 works as a current-voltage conversion circuit. The anode of the PD1 is connected to the ground potential. In addition the current-voltage conversion resistor Rg_A is connected between the inverting input terminal and the output terminal of the AMP1. The impedance matching resistor Rref_A is connected between the non-inverting input terminal of the AMP1 and the reference voltage Vref. The output of the AMP1 is connected to each of non-inverting input terminals of amplifiers AMP2 and AMP3. Here, the AMP2 and AMP3 work as non-inverting voltage amplifying circuits.

The feedback resistor R2 is connected between the inverting input terminal and the output terminal of the AMP2. The gain resistor R1 and the SW1 are connected with each other in series between the inverting input terminal of the AMP2 and the reference voltage Vref. A gain resistor R15 is also connected between the inverting input terminal of the AMP2 and the reference voltage Vref. The feedback resistor R4 is connected between the inverting input terminal and the output terminal of the AMP3. The gain resistor R3 and the SW2 are connected with each other in series between the inverting input terminal of the AMP3 and the reference voltage Vref. A gain resistor R16 is also connected between the inverting input terminal of the AMP3 and the reference voltage Vref.

When the SW1 and the SW2 are off, the gains of the AMP2 and the AMP3 are respectively determined by (R1+R2)/R1 and (R3+R4)/R3. When the SW1 and the SW2 are on, the gains of the AMP2 and the AMP3 are respectively determined by (R1//R15+R2)/(R1//R15) and (R3//R16+R4)/(R3//R16). Thus any given gain can be selected out of four gains in total.

The AMP2 and the AMP3 are controlled by the SW signal so that one of the AMP2 and the AMP3 whichever can obtain the set gain is activated, and the other is disabled. The SW1 and the SW2 are activated by an SW11 signal for switching gains. The SW signal and the SW11 signal are not necessarily synchronized each other.

Described next is an operation of the received-light amplifying circuit according to Embodiment 3. The SW signal and the SW11 signal are asynchronous. Depending on the SW signal and the SW11 signal, the received-light amplifying circuit according to Embodiment 3 can be activated with any given combination out of the following four combinations; the SW1 and the AMP2 are on, the SW1 and the AMP3 are on, the SW2 and the AMP2 are on, and the SW2 and the AMP3 are on. Any given gain can be selected out of four gains. Since the additional R15 and R16 alone can increase the variety of gains to be set, the received-light amplifying circuit according to Embodiment 3 is suitable to a received-light amplifying circuit for the optical pick up which can handle optical discs without an increase in cost.

In particular, received-light amplifying circuits for the optical pick up use optical media to change the ratio of (i) an electric signal generated out of the main beam to (ii) an electric signal generated out of a sub beam. An ideal received-light amplifying circuit has a greater variety of gains to be set. Embodiment 3 introduces such an excellent received-light amplifying.

Described next is an optical disc apparatus, using the received-light amplifying circuit in the present invention.

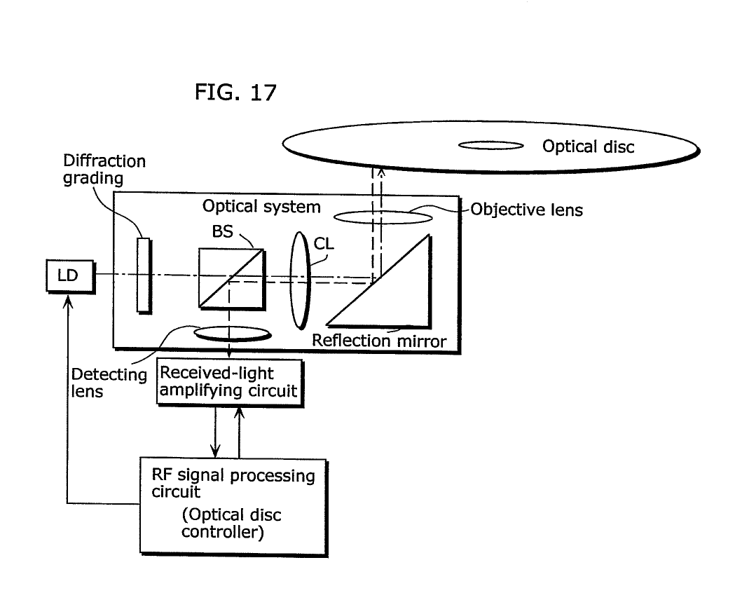

FIG. 17 is a schematic diagram showing an example of an optical disc apparatus using the received-light amplifying circuit in the present invention. The optical disc apparatus mainly includes a received-light amplifying circuit, a laser diode (LD), an optical system, and an RF signal processing circuit.

A beam emitted from the LD is split into three beams by a diffraction grading. Hereinafter, FIG. 17 shows a representative beam only.

Split by the diffraction grading, each of the beams travels through a beam splitter and a collimator lens. Then the beam is refracted by the reflection mirror, and focused on an optical disc by an objective lens. Each of the beams focused on the optical disc reflects off the optical disc, and passes through the objective lens, the reflection mirror, the CL, the BS, and a detecting lens. Then the beam is emitted on a light-receiving element of the received-light amplifying circuit.

A light signal included in the emitted beam is photo-electrically converted into an electric signal by the received-light amplifying circuit. The electric signal is transmitted to the RF signal processing circuit to rectified and processed. Here the gain needs to be changed since the power of the incoming light signal into the received-light amplifying circuit differs depending on the difference in refractivity according to the kind of the optical disc. The present invention can implement a received-light amplifying circuit which is capable of (i) selecting multiple gains in order to handle many kinds of optical discs, and (ii) having excellent high-frequency characteristics.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

As described above, the present invention is used for semiconductor devices including light-receiving elements. In particular, the present invention is useful to a received-light amplifying circuit including a gain-switching circuit employing a switching device, and to an optical disc apparatus including the received-light amplifying circuit.

What is claimed is:

1. A received-light amplifying circuit comprising:
a current-voltage conversion circuit which converts a current signal provided from a light-receiving element into a voltage signal;
differential voltage amplifying circuits each of which has a non-inverting input terminal connected to an output terminal of said current-voltage conversion circuit;
an output terminal which has a common connection to output terminals of said differential voltage amplifying circuits;
feedback resistors each of which is connected between said output terminal and an inverting input terminal of a corresponding one of said differential voltage amplifying circuits;
gain resistors each of which is connected between said inverting input terminal of the corresponding one of said voltage amplifying circuits and a reference voltage; and
one or more control units each of which is (i) provided with the corresponding one of said differential voltage amplifying circuits, (ii) connected, between said output terminal and the reference voltage, in series to a corresponding one of said feedback resistors and to a corresponding one of said gain resistors, and (iii) configured to control a connection between said output terminal and the reference voltage in response to a signal from an outside.

2. The received-light amplifying circuit according to claim 1,
wherein each of said control units is a switch connected between said gain resistor and the reference voltage.

3. The received-light amplifying circuit according to claim 2,
wherein, in response to the signal from outside, any one of said differential voltage amplifying circuits is selectively activated, and any one of the switches for disabled one of said differential voltage amplifying circuits turns off.

4. The received-light amplifying circuit according to claim 2,
wherein the switch includes a buffer circuit, and an output voltage from the buffer circuit and an offset voltage from said current-voltage conversion circuit have opposite temperature characteristics curves.

5. The received-light amplifying circuit according to claim 2,
wherein each of said differential voltage amplifying circuits includes: differential amplifying units each of which is provided for a corresponding one of said voltage amplifying circuits; and a buffer unit configured to receive in common outputs from said differential amplifying units.

6. The received-light amplifying circuit according to claim 5,
wherein each of said differential amplifying units has resistors connected between (i) emitters of transistors included in each of said differential amplifying units and (ii) a current source which drives said differential amplifying units, each of the resistors having a different value for the corresponding one of said differential amplifying units.

7. The received-light amplifying circuit according to claim 2,
wherein said one or more control units include switches each connected between the corresponding one of said feedback resistors and the output terminal, and is structure-wise similar to the switch connected between the corresponding one of said gain resistors and the reference voltage.

8. The received-light amplifying circuit according to claim 1,
wherein each of said one or more control units is configured to switch values of the corresponding one of said gain resistors.

9. An optical disc apparatus including said received-light amplifying circuit according to claim 1.
